(19) United States
(12) Patent Application Publication
(10) Pub. No.: US 2014/0284730 A1
(43) Pub. Date: Sep. 25, 2014

(54) MEMS DEVICE AND METHOD OF MANUFACTURING THE SAME

(71) Applicant: KAIBUSHIKI KAISHA TOSHIBA, Tokyo (JP)

(72) Inventor: Tomohiro SAITO, Yokohama-shi (JP)

(21) Appl. No.: 13/965,133

(22) Filed: Aug. 12, 2013

(30) Foreign Application Priority Data
Mar. 19, 2013 (JP) 2013-057278

(51) Int. Cl. B81B 3/00; B81C 1/00

(52) U.S. Cl. CPC B81B 3/0021; B81C 1/00182
USPC 257/415; 438/50

(57) ABSTRACT

According to one embodiment, a MEMS device comprises a first electrode provided on a support substrate, a burying insulating film formed at the sides of the first electrode, and a second electrode opposed to the first electrode, having ends extending outside the ends of the first electrode and able to move in the direction it is opposed to the first electrode.

### CROSS-REFERENCE TO RELATED APPLICATIONS

This application is based upon and claims the benefit of priority from Japanese Patent Application No. 2013-057278, filed Mar. 19, 2013, the entire contents of which are incorporated herein by reference.

### FIELD

Embodiments described herein relate generally to a MEMS device and a method of manufacturing the same.

### BACKGROUND

A micro-electromechanical system (MEMS) device, which comprises a movable electrode and a fixed electrode, has a low loss, high insulating property, and high linearity. It attracts much attention, as a key device in the next-generation mobile telephones. Further, a MEMS capacitor has been proposed, which makes good use of the MEMS device and which can have a variable electrostatic capacitance.

In the MEMS capacitor, the upper electrode (movable electrode) may fail to have a flat surface in some cases, because of the projection-depression pattern of the lower electrode (fixed electrode) positioned beneath the upper electrode. For example, at that part of the lower electrode, which has a pattern edge, the upper electrode is bent downward due to the pattern edge. In this case, the upper electrode inevitably contact the edge of the lower electrode when the device is driven with the voltage applied between the upper and lower electrodes. As a result, the upper electrode and the lower electrode, which occupy a larger part of the capacitor area will not contact as much as desired.

Thus, the capacitor comprising an upper electrode and a lower electrode (and, in addition, an insulating film formed on the lower electrode) fails to acquire a sufficient capacitance. To make the upper and lower electrodes contact sufficiently, the voltage applied between the electrodes may be raised. If the voltage is raised, however, the gap between the electrodes will change. Hence, a high voltage must be applied to achieve full saturation of capacitance, causing a problem.

### BRIEF DESCRIPTION OF THE DRAWINGS

FIG. 1 is a plan view outlining the configuration of a MEMS device according to a first embodiment;

FIGS. 2A and 2B are sectional views taken along lines A-A′ and B-B′ shown in FIG. 1, respectively;

FIGS. 3A to 3H are sectional views showing the steps of manufacturing the MEMS device according to the first embodiment;

FIG. 4 is a sectional view showing the major parts constituting a MEMS device according to a second embodiment;

FIGS. 5A to 5D are sectional views showing the steps of manufacturing the MEMS device according to the second embodiment;

FIG. 6 is a sectional view showing a modification of the second embodiment;

FIGS. 7A to 7D are sectional views showing the steps of manufacturing a MEMS device according to a third embodiment;

FIG. 8 is a plan view outlining the configuration of a MEMS device according to a fourth embodiment; and

FIG. 9 is a sectional view taken along line B-B′ shown in FIG. 8.

### DETAILED DESCRIPTION

In general, according to one embodiment, a MEMS device comprises a first electrode provided on a support substrate, a burying insulating film formed at the sides of the first electrode, and a second electrode opposed to the first electrode, having ends extending outside the ends of the first electrode and able to move in the direction it is opposed to the first electrode.

MEMS devices according to embodiments will be described with reference to the accompanying drawings. The embodiments described below are MEMS devices in which the electrostatic capacitance can be varied. Nonetheless, the invention is not limited to such devices, and can be applied to switching elements.

### First Embodiment

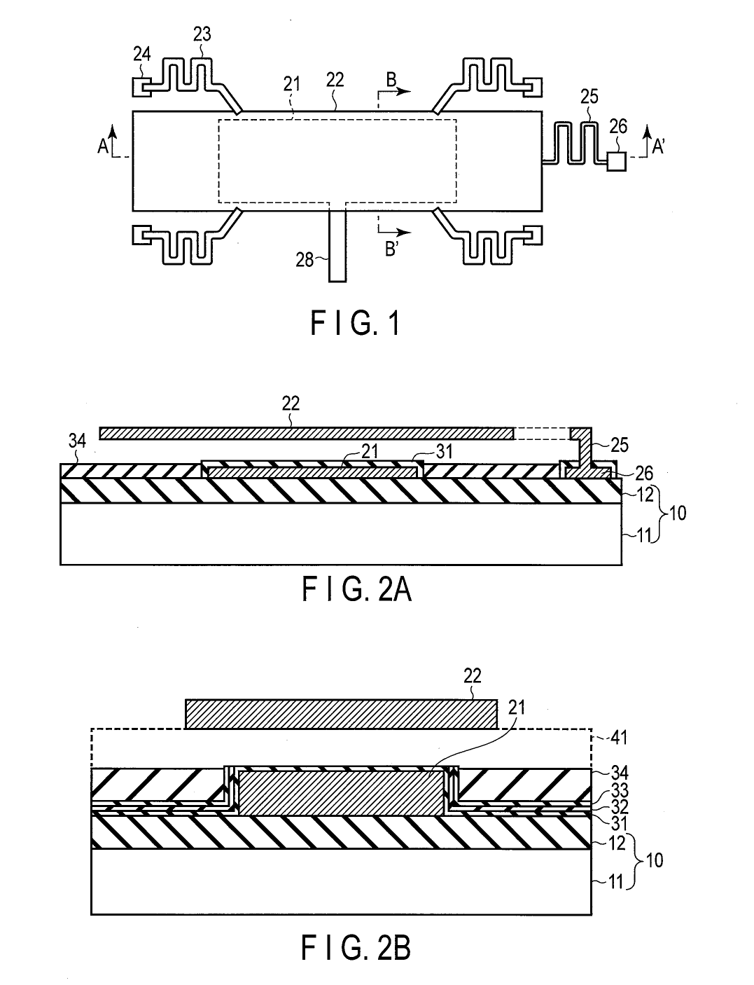

FIG. 1 is a plan view outlining the configuration of a MEMS device according to a first embodiment. FIG. 2A is a sectional view taken along line A-A′ shown in FIG. 1. FIG. 2B is a magnified sectional view taken along line B-B′ shown in FIG. 1. In FIG. 2A, a part of the burying insulating film is not shown. This embodiment is a device of the type that is driven with an electrostatic force as a voltage is applied between the upper and lower electrodes.

In FIGS. 2A and 2B, number 10 designates a support substrate composed of a Si substrate 11 and an insulating film 12, for example, silicon oxide film, formed on the Si substrate 11. The support substrate 10 may incorporate elements, such as field-effect transistors constituting a logic circuit and a memory circuit.

On the support substrate 10, a lower electrode (first electrode) 21 is provided and used as fixed electrode. The lower electrode 21 is, for example, rectangular, and is made of, for example, aluminum (Al) or an Al alloy consisting mainly of aluminum. The material of the lower electrode 21 is not limited to these. Instead, the lower electrode 21 may be made of copper (Cu), platinum (Pt), tungsten (W), or the like. The lower electrode 21 is connected to a wire 28 made of the same material as the lower electrode 21, and is thereby connected to various circuits, the ground, or the like.

A capacitor insulating film 31 comprising, for example, a silicon nitride film, and having a thickness of 100 nm is formed, covering the surface of the lower electrode 21. The material of the capacitor insulating film 31 is not limited to a silicon nitride film. The capacitor insulating film 31 may be a high-k film instead, which had a larger dielectric constant than SiO and SiN.

At the sides of the lower electrode 21, a burying insulating film 34 is formed, which comprises a silicon oxide film. The burying insulating film 34 therefore reduces the step defined by the upper surface and any side of the lower electrode 21. More specifically, as shown in FIG. 2B, the capacitor insulating film 31 is formed, covering the surfaces of the lower electrode 21 and support substrate 10. Further, at the sides of the lower electrode 21 and the support substrate 10, a buffer film 32 consisting of silicon oxide and a stopper film 33 consisting of silicon nitride are formed on the capacitor insulating film 31. Still further, at the sides of the lower electrode 21, the burying insulating film 34 comprising a silicon oxide film is formed on the stopper film 33. The upper surface of the burying insulating film 34 is level with or below the upper surface of the lower electrode 21.

An upper electrode (second electrode) 22, or a movable electrode, is arranged above the lower electrode 21 and opposed to the lower electrode 21. The upper electrode 22 is rectangular and larger than the lower electrode 21, overlapping the lower electrode 21. Thus, the ends of the upper electrode 22 lie outside the ends of the lower electrode 21. The upper electrode 22 is made of, for example, a low-resistance material such as Al, an Al alloy, Cu, Au or Pt. The material of the upper electrode 22 is not limited to a ductile material, nevertheless. The upper electrode 22 may be made of a brittle material such as tungsten (W).

As shown in FIG. 1, the lower electrode 21 and the upper electrode 22 are rectangular as seen from above. They may be shaped like a square, a circle or an ellipsis, instead.

The upper electrode 22 is connected, at some parts, to anchor parts 24 provided on the support substrate 10, by first spring parts (beam parts) 23. The first spring parts 23 and the anchor parts 24 are provided at several positions (for example, four positions). The first spring parts 23 are, for example, silicon nitride films, have meandering shape, and has elasticity. These spring parts 23 enable the upper electrode 22 to move up and down.

The upper electrode 22 is connected, at one part, to an anchor part 26 provided on the substrate 10, by a second spring part 25 made of an electrically conductive material. The second spring part 25 may be made integral with the upper electrode 22 and may extend therefrom. The second spring part 25 achieves electrical conduction with the upper electrode 22, and is very slender and made of an elastic material such as Al.

A dome layer (not shown) may be provided, covering the space in which the upper electrode 22, spring parts 23 and 25 can move.

In this embodiment, the lower electrode 21 is buried, at sides, by the burying insulating film 34. The upper electrode 22 can therefore be formed on a flat sacrificial layer, which will be described later. This helps suppress the bending of the upper electrode 22.

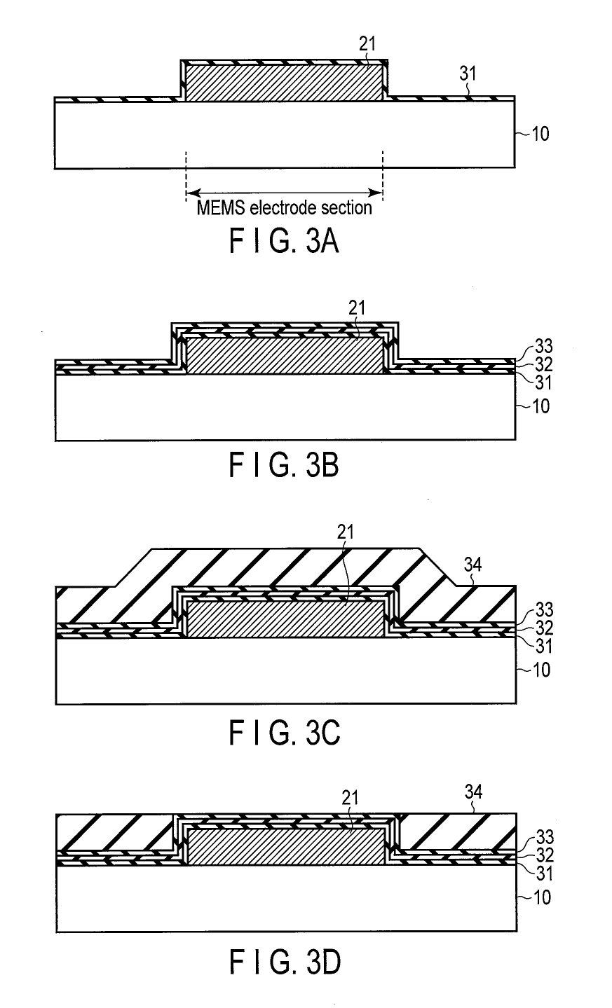

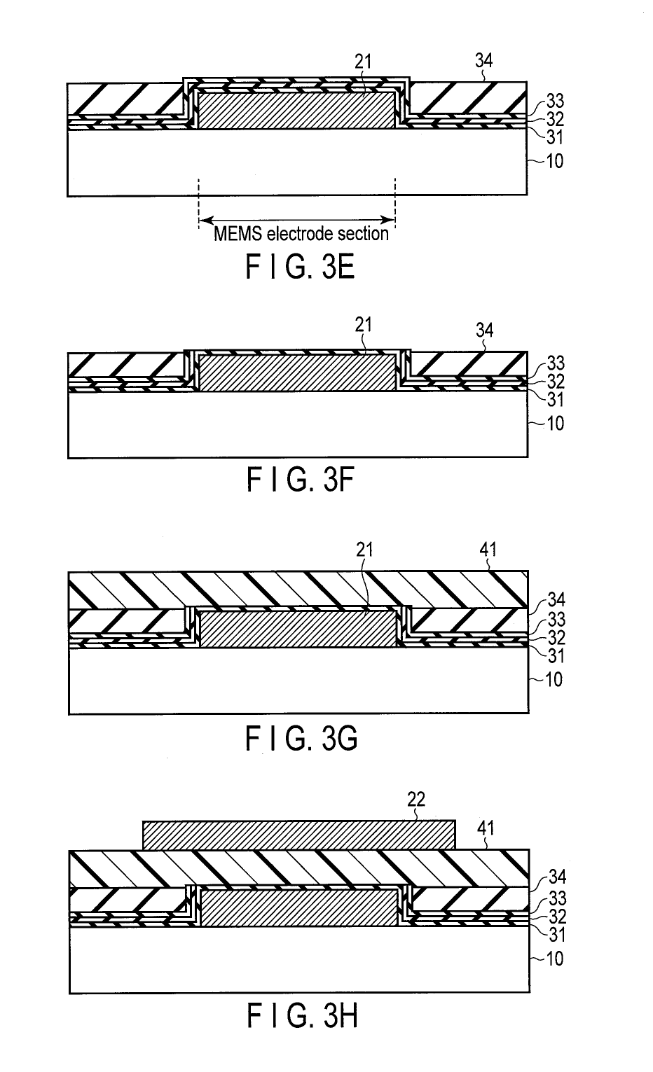

A method of manufacturing the MEMS device according to this embodiment will be explained with reference to FIGS. 3A to 3H. FIGS. 3A to 3H are equivalent to the sectional views taken along line B-B′ shown in FIG. 1.

First, as shown in FIG. 3A, an electrode material (for example, an Al alloy) for forming a lower signal electrode or a lower drive electrode and for forming wires for the electrode are applied to the entire surface of the support substrate 10 comprising the substrate 11 made of, for example, Si and the insulating film 12 formed on the substrate 11. The electrode material is then patterned, forming an electrode and wires. In FIG. 3A, only a part of the lower electrode (first electrode) 21 is shown. The patterning of the electrode material can be achieved by, for example, transfer using resist and anisotropic etching. The lower electrode 21 has a height of, for example, 1 μm.

Then, a silicon nitride film (capacitor insulating film) 31, for example, which will serve as a capacitor insulator, is formed on the substrate 10, covering the lower electrode 21, by means of deposition and patterning. The capacitor insulating film 31 has thickness of, for example, 100 nm.

Next, as shown in FIG. 3B, a buffer film 32 comprising, for example, a silicon oxide film, and a stopper film 33 comprising, for example, a silicon nitride film are deposited in the order mentioned. These films have thickness of 10 to 500 nm. The stopper film 33 is formed in order to prevent the buffer film 32 from being etched when the sacrificial layer (later described) is etched back. The buffer film 32 is formed in order to prevent the capacitor insulating film 31 from being damaged when the stopper film 33 is etched.

Further, as shown in FIG. 3C, a burying insulating film 34 comprising, for example, a silicon oxide film, is formed by means of, for example, the CVD method. The thickness of the burying insulating film 34 is 1.8 to 2.0 μm. The thickness of the buffer film 32, the stopper film 33, and that of the burying insulating film 34 can be changed as needed, because they depend on the thickness of the lower electrode 21.

Next, as shown in FIG. 3D, chemical mechanical polishing (CMP) is performed, polishing the burying insulating film 34. Specific conditions should better be set to stop the polishing at the upper surface of the stopper film 33. This helps improve the flatness the lower electrode 21 has with respect to other parts.

Then, as shown in FIG. 3E, a dry etching process or a wet etching process is performed, etching the upper surface of the burying insulating film 34. The amount of this etching is approximately the sum of the thickness of the buffer layer 32 and that of the stopper film 33. A representative example of dry etching is reactive ion etching (RIE). In the wet etching, a solution containing fluorine acid is used if the burying insulating film 34 is an oxide film.

As shown in FIG. 3F, that part of the stopper film 33, which exists above the lower electrode 21, is removed by dry etching such as chemical dry etching (CDE), exposing a part of the buffer film 32. The exposed part of the buffer film 32 is removed by a wet process. As a result, the capacitor insulating film 31, which is formed on the lower electrode 21, is exposed, and the lower electrode 21 is buried at sides by the burying insulating film 34.

Next, as shown in FIG. 3G, a first sacrificial layer 41 consisting of an organic material such as polyimide is formed by coating on the entire surface of the structure. The first sacrificial layer 41 is removed later to provide a space between the lower electrode 21 and the upper electrode 22.

At this point, those parts of the sacrificial layer 41, which lie above the lower signal electrode or lower drive electrode and above the wires, particularly the part on which the upper electrode 22 will be formed, are made almost flat. Then, the sacrificial layer 41 is patterned to form anchor parts for positioning the upper electrode 22. The sacrificial layer 41 is patterned by, for example, transfer using resist and etching.

Further, as shown in FIG. 3H, an upper electrode material is applied, forming a layer. The layer is patterned, forming an upper electrode 22, a drive electrode and a bias line. In FIG. 3H, only the upper electrode 22 is shown. At this point, that part of the lower surface of the upper electrode 22, which opposes the lower electrode 21, is almost flat.

Next, first spring parts 23 (not shown) are formed, which supports the upper electrode 21. The sacrificial layer 41 is then removed. A structure is thereby provided, in which the upper electrode 22 is supported in a space. A second spring part 25 can be formed at the same time the first spring parts 23 are formed.

In the following steps, a second sacrificial layer is formed on the upper electrode in the same way as hitherto practiced, to provide a space between the upper electrode and a dome layer. The dome layer is then formed. Then, the dome layer is patterned, forming a hole through which to remove the first and second sacrificial layer. Further, using the hole made in the dome layer, the first and second sacrificial layers are etched, forming a dome covering the structure.

In this embodiment, the burying insulating film 34 is formed at the sides of the lower electrode 21, reducing the step defined by the upper surface and any side of the lower electrode 21. The sacrificial layer 41 can therefore has an almost flat surface. The electrically conductive layer to process to form the upper electrode 22 is formed on the sacrificial layer 41 that is improved in flatness. This can suppress the bending of the upper electrode 22. Since the bending of the upper electrode 22 is suppressed, the capacitor capacitance can be decreased while the upper electrode 22 remains floating (in off state), maintaining or extending the variable capacitance range of the capacitor. Hence, a MEMS device comprising a variable capacitance capacitor and a switch and having excellent capacitance characteristic can be realized.

### Second Embodiment

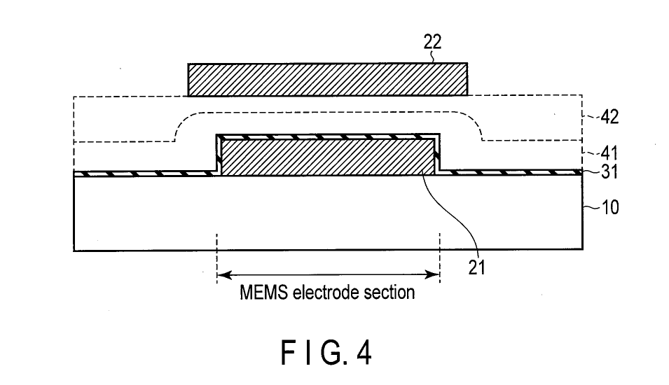

FIG. 4 is a sectional view showing the major parts constituting a MEMS device according to a second embodiment, and is a sectional view taken along line B-B′ shown in FIG. 1. The components identical to those shown in FIG. 2B are designated by the same reference numbers and will not be described in detail.

This embodiment differs from the first embodiment described above, in that the upper electrode 22 is formed almost flat without providing the burying insulating film 34. That is, the upper electrode 22 is formed almost flat as will be explained below, though the burying insulating film 34 is not used.

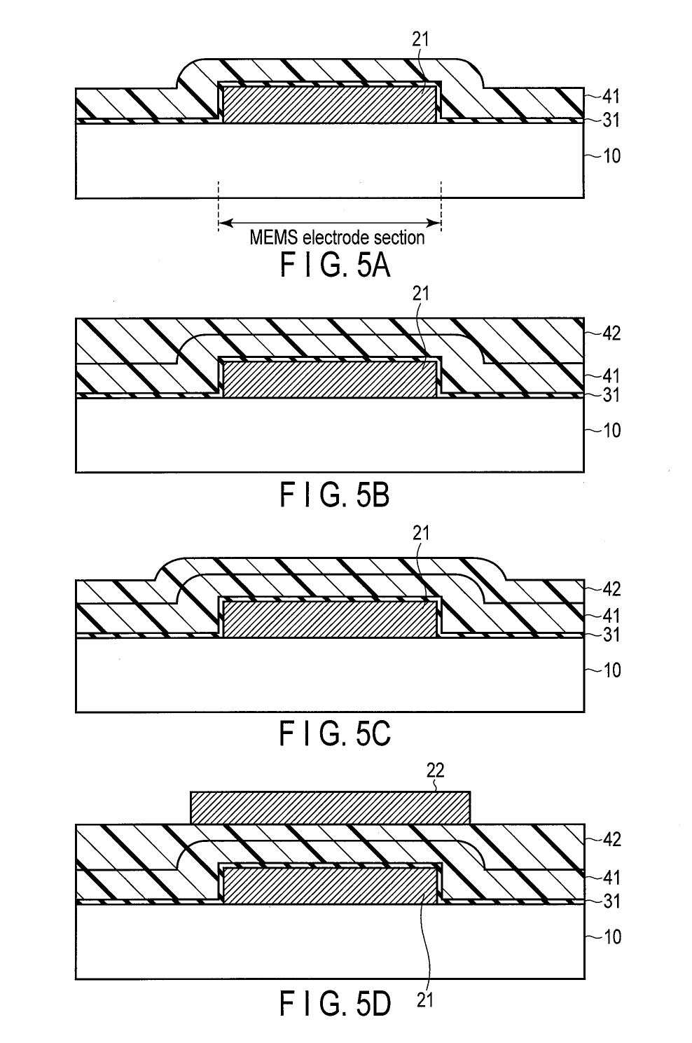

A method of manufacturing a MEMS device according to this embodiment will be explained with reference to FIGS. 5A to 5D.

First, as shown in FIG. 3A, an electrode material for forming a lower signal electrode or a lower drive electrode and for forming wires for the electrode is applied to a support substrate 10. The electrode material is patterned, forming a lower electrode 21.

Next, as shown in FIG. 5A, a first sacrificial layer 41 consisting of organic material such as polyimide is formed, by coating, on the entire surface of the structure. Then, patterning is performed at necessary parts (not shown).

Then, as shown in FIG. 5B, a second sacrificial layer 42 consisting of organic material such as polyimide is formed, by coating, on the entire surface of the structure. Patterning is then performed at necessary parts (not shown). The pattern of the second sacrificial layer 42 completely covers the first sacrificial layer 41. The sum of the height of the first sacrificial layer 41 and that of the second sacrificial layer 42 is equivalent to the gap between the lower electrode 21 and the upper electrode 22. Since two sacrificial layers are formed, the depressions and projections each sacrificial layer has at upper surface due to the lower electrode pattern are more moderated than in the case where only one sacrificial layer is used.

The surface of the second sacrificial layer 42 need not be perfectly flat, and may reflect the step of the first sacrificial layer 41 as shown in FIG. 5C. In this case, too, the surface of the second sacrificial layer 42 is almost flat at the part extending between two positions at a short distance from the edges of the first sacrificial layer 41.

Next, as shown in FIG. 5D, an electrically conductive film is deposited and patterned, forming an upper electrode 22. Since two sacrificial layers have been formed, the lower surface of the upper electrode 22 is almost flat lower surface like the upper surfaces of the sacrificial layers. Those parts of the upper electrode 22, which lie above the end parts of the lower electrode 21, are formed almost flat. The device can therefore acquire capacitance large enough to function as a capacitor.

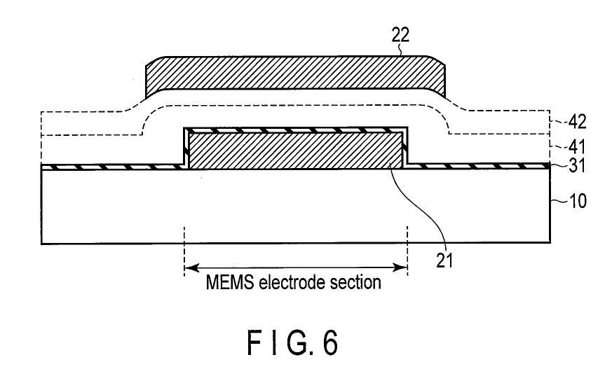

If the second sacrificial layer 42 reflects the step of the first sacrificial layer 41 as shown in FIG. 5C, the end parts of the upper electrode 22 will bend as shown in FIG. 6. However, this does not adversely influence the capacitor characteristic because the bending parts of the upper sacrificial layer 22 exist outside the end parts of the lower electrode 21.

The two sacrificial layers are formed by repeating coating and patterning two times. The coating and the patterning may be repeated more times to form more sacrificial layers. Further, the first sacrificial layer 41 and the second sacrificial layer 42 need not consist of the same material. Still further, the materials of the second sacrificial layer 42 may be applied after applying the material of the first sacrificial layer 41, and both layers thus formed may be patterned at the same time to form the sacrificial layers 41 and 42.

In this embodiment, a plurality of sacrificial layers are formed by repeating deposition and patterning, to provide a space between the lower electrode 21 and the upper electrode 22. The depressions and projections each sacrificial layer has at upper surface due to the lower electrode pattern are therefore less deep and less high than otherwise. This moderates the influence of the step of the lower electrode 21, ultimately suppressing the bending of the edge parts of the upper electrode 22. The second embodiment can therefore achieve the same advantage as the first embodiment.

### Third Embodiment

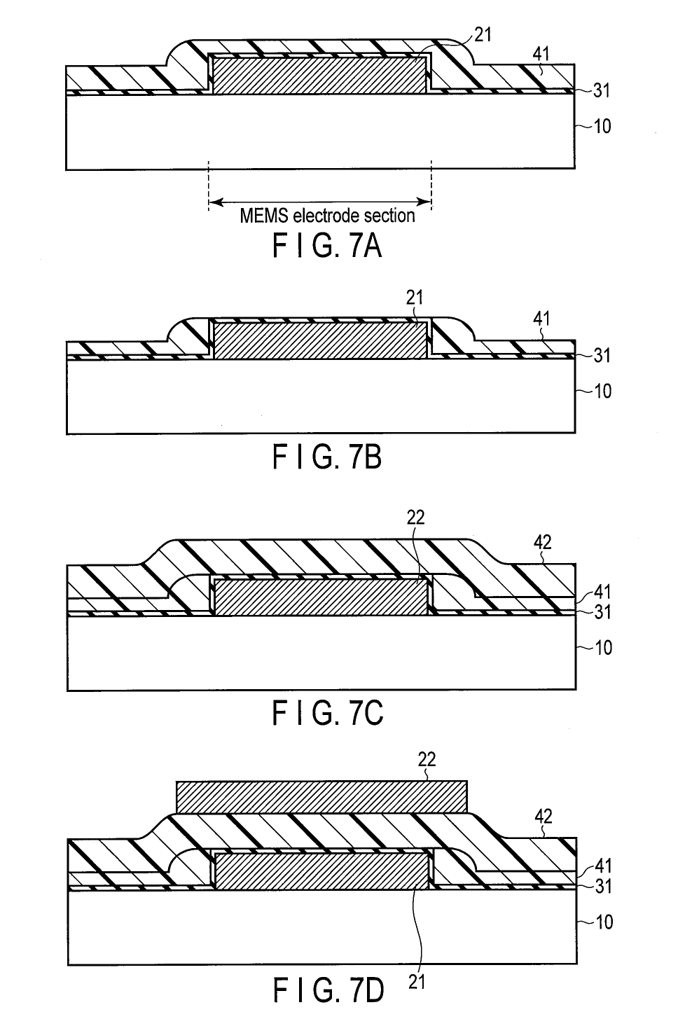

FIGS. 7A to 7D are sectional views showing the steps of manufacturing a MEMS device according to a third embodiment. The components identical to those shown in FIGS. 5A to 5D are designated by the same reference numbers and will not be described in detail.

This embodiment differs from the second embodiment described above, in that an etch-back process is performed on the first sacrificial layer.

In this embodiment, as shown in FIG. 7A, a lower electrode 21 is formed on a support substrate 10, and a capacitor insulating film 31 is then formed on the lower electrode 21. Then, a first sacrificial layer 41 is formed on the entire surface of the resultant structure, and is patterned.

Next, as shown in FIG. 7B, the first sacrificial layer 41 is etched back, exposing the surface of the capacitor insulating film 31. As a result, those parts of the first sacrificial layer 41, which are near the sides of the lower electrode 21, lie at almost the same level as the upper surface of the lower electrode 21, and other parts of the first sacrificial layer 41 lie at a lower level than the upper surface of the lower electrode 21.

Then, as shown in FIG. 7C, a material is applied to the exposed part of the capacitor insulating film 31 and to the first sacrificial layer 41. At this point, the second sacrificial layer 42 need not have a flat surface by all means. The surface of the second sacrificial layer 42 may reflect the step of the underlying layer. The surface of the capacitor insulating film may not be exposed. In this case, the distance between the electrodes is determined by the laminate composed of the remaining part of the first sacrificial layer 41 and the second sacrificial layer 42.

Further, as shown in FIG. 7D, an electrically conductive film is deposited on the second sacrificial layer 42 and patterned, thereby forming an upper electrode 22.

In this embodiment, too, the end parts of the upper electrode 22 may bend. If the upper electrode 22 bends, however, it bends at outward parts far from the end parts of the lower electrode 21, because the lower electrode 21 is buried, at sides, by the first sacrificial layer 41 and the steps at the sides of the lower electrode 21 are therefore small. Hence, the bending of the upper electrode 22 causes no problem.

As described above, a plurality of sacrificial layers are formed, one by one, to provide a space between the lower electrode 21 and the upper electrode 22. In addition, the first sacrificial layer 41 is etched back. As a result, the flatness of the sacrificial layers increases, in spite of the depressions and projections formed at the upper surface due to the pattern of the lower electrode. The embodiment can therefore achieve the same advantage as the second embodiment. Further, the distance between the lower electrode 21 and the upper electrode 22 is determined by only the thickness of the second sacrificial layer 42, because the first sacrificial layer 41 is etched back.

### Fourth Embodiment

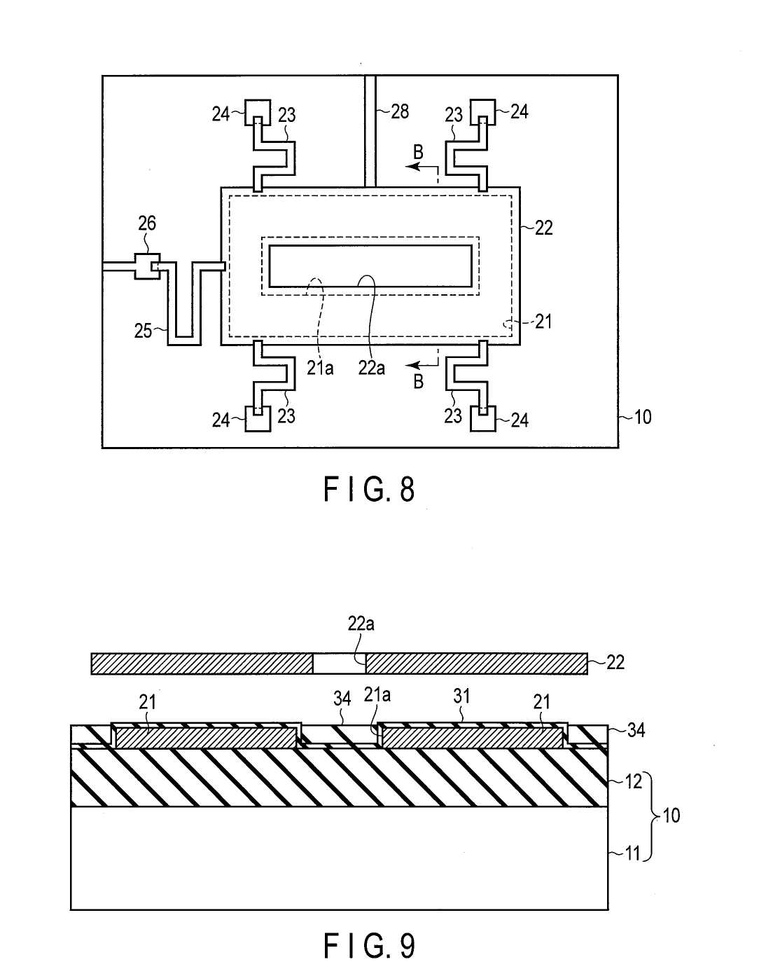

FIG. 8 is a plan view outlining the configuration of a MEMS device according to a fourth embodiment. FIG. 9 is a sectional view taken along line B-B′ shown in FIG. 8. The components identical to those shown in FIG. 1, FIGS. 2A and 2B are designated by the same reference numbers and will not be described in detail.

This embodiment is applied to an electrode structure having a slit, and is basically similar to the first embodiment.

The lower electrode 21 has a slit 21a in the center part. Slit 21a extends parallel to the lengthwise direction of the electrode 21. The upper electrode 22 also has a slit 22a that is aligned with slit 21a. The upper electrode 22 is formed larger than the lower electrode 21, and slit 22a made in the upper electrode 22 is smaller than slit 21a made in the lower electrode 21. That is the upper electrode 22 is provided, overlapping the entire lower electrode 21.

A capacitor insulating film 31 is formed, covering the lower electrode 21. A burying insulating film 34 is formed at the sides of the lower electrode 21, and another insulating film 34 is formed in slit 21a. The burying insulating films 34 therefore decrease the steps at the edges of the lower electrode 21. A buffer film 32 and a stopper film 33 (neither shown in FIG. 9) may be formed at the sides of the lower electrode 21 and in slit 21a, as in the first embodiment.

In this configuration, the burying insulating film is formed not only at the sides of the lower electrode 21, but also in slit 21a made in the lower electrode 21. The sacrificial layer used to form the upper electrode 22 can therefore have an almost flat surface. This can suppress the bending of the upper electrode 22, in spite of the depressions and projections formed due to the edges of the lower electrode 21. Hence, the third embodiment can therefore achieve the same advantage as the first embodiment.

### Modified Embodiments

This invention is not limited to the embodiments described above.

In any embodiment described above, a buffer film and a stopper film are formed in order to suppress the damage the capacitor insulating film receives when the sacrificial layer is etched back. Nonetheless, the buffer film and the stopper film need not be formed if the damage to the capacitor insulating film does not cause a problem.

The support substrate is not limited one composed of a Si substrate and a silicon oxide film formed on the Si substrate. An insulating substrate made of, for example, glass can be used instead. Further, the beam parts provided for the upper electrode need not be made of a material different from the material of the upper electrode. Rather, they may be made of the same material as the upper electrode, and may be formed at the same time as the upper electrode.

Any embodiment described above is a device driven with an electrostatic force generated by applying a voltage between the upper and lower electrodes. Nonetheless, this invention can be applied to a MEMS structure which has electrodes made of different metals and laid one on the other, and which is driven by the piezoelectric force generated by the laminate composed of these electrodes.

Any embodiment described above is a MEMS capacitor. This invention can be applied to a MEMS switch, nevertheless. In this case, a part of the capacitor insulating film formed on the lower electrode, for example that part contacting the upper signal electrode, is removed by means of patterning and etching, thereby exposing the surface of the lower electrode. As a result, the upper electrode and the lower electrode constitute a switch. As the electrodes are driven by upper and lower drive electrodes, respectively, the structure operates as a switch.

Any embodiment described above has two electrodes, i.e., lower electrode and upper electrode. Nonetheless, this invention can be applied to a MEMS device having three or more electrodes (for example, fixed upper electrode, fixed lower electrode and movable intermediate electrode). Moreover, each electrode can be set to any size, in accordance with the electrostatic capacitance required.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A MEMS device comprising:
a first electrode provided on a support substrate;
a burying insulating film formed at the sides of the first electrode; and
a second electrode opposed to the first electrode, having ends extending outside the ends of the first electrode and able to move in the direction it is opposed to the first electrode.

2. The device according to claim 1, further comprising beam parts connecting the support substrate and the second electrode and elastically supporting the second electrode.

3. The device according to claim 2, which further comprises anchor parts provided on the support substrate, and in which the beam parts are connected, at one end, to the anchor parts, respectively, and at the other end, to the second electrode.

4. The device according to claim 1, wherein the burying insulating layer has an upper surface at a level lower than the upper surface of the first electrode.

5. The device according to claim 1, wherein the burying insulating layer is a silicon oxide film.

6. The device according to claim 1, wherein the burying insulating layer is a multi-layer film comprising a silicon oxide nitride film and a silicon nitride film.

7. The device according to claim 1, wherein a capacitor insulating film is formed, covering the first electrode.

8. The device according to claim 1, wherein a capacitor insulating film comprising a silicon nitride film is formed on the support substrate, covering the first electrode, and a buffer film comprising a silicon oxide film and a stopper film comprising a silicon nitride film are formed on the capacitor insulating film, at the sides of the first electrode and above the support substrate.

9. The device according to claim 1, wherein the support substrate comprises a silicon substrate and a silicon oxide film formed on the silicon substrate.

10. A method of manufacturing a MEMS device, comprising:
forming a first electrode on a part of a support substrate;
forming a burying insulating film at sides of the first electrode;
forming a sacrificial layer on the first electrode and the burying insulating film;
forming a second electrode on the sacrificial layer; and
removing the sacrificial layer after the second electrode has been formed.

11. The method according to claim 10, wherein the burying insulating film is formed by first depositing the burying insulating film on the support substrate, covering the first electrode, and then removing the burying insulating film on the first electrode by means of polishing.

12. The method according to claim 11, wherein the burying insulating layer is a multi-layer film comprising a silicon oxide nitride film and a silicon nitride film.

13. The method according to claim 10, wherein the sacrificial layer is made of an organic material.

14. The method according to claim 10, wherein beam parts are provided, elastically supporting the second electrode, before the sacrificial layer is removed after the second electrode has been formed.

15. A method of manufacturing a MEMS device, comprising:
forming a first electrode on a part of a support substrate;
forming a first sacrificial layer on the support substrate and the first electrode;
forming a second sacrificial layer on the first sacrificial layer;
forming a second electrode on the second sacrificial layer; and
removing the first and second sacrificial layers after the second electrode has been formed.

16. The method according to claim 15, wherein the first sacrificial layer is etched back and removed before the second sacrificial layer is formed, and the second sacrificial layer is formed on the first sacrificial layer and the first electrode.

17. The method according to claim 15, wherein the first and second sacrificial layers are made of an organic material.

18. The method according to claim 15, wherein beam parts are provided, elastically supporting the second electrode, before the sacrificial layer is removed after the first and second electrode has been formed.
